(19) United States
(12) Patent Application Publication
(10) Pub. No.: US 2011/0300473 A1
(43) Pub. Date: Dec. 8, 2011

(54) METHOD FOR NANOPATTERNING USING NANOMASKS AND LIGHT EXPOSURE

(75) Inventor: Jin Ji, Boston, MA (US)

(73) Assignee: Lightware Power, Inc., Cambridge, MA (US)

(21) Appl. No.: 13/152,282

(22) Filed: Jun. 3, 2011

Related U.S. Application Data
(60) Provisional application No. 61/351,640, filed on Jun. 4, 2010.

(51) Int. Cl. G03F 7/20; G03F 1/00

(52) U.S. Cl. 430/5; 430/325; 430/323

(57) ABSTRACT

A nanomask for generating an illumination pattern includes a layer having a first surface and a second surface and a plurality of resonant nano-features disposed on at least a selected one of the first surface and the second surface. The nanomask is configured to provide an illumination pattern adjacent to the second surface. The illumination pattern has dimensions smaller than a wavelength λ of electromagnetic radiation used to illuminate the first surface of the layer in a single illumination. A nanopatterning method is also described.

### CROSS-REFERENCE TO RELATED APPLICATIONS

This application claims priority to and the benefit of co-pending U.S. provisional patent application Ser. No. 61/351,640, METHOD FOR NANOPATTERNING USING NANOMASKS AND LIGHT EXPOSURE, filed Jun. 4, 2010, which application is incorporated herein by reference in its entirety.

### FIELD OF THE INVENTION

The invention relates to photolithography in general and particularly to a photolithography process mask.

### BACKGROUND OF THE INVENTION

Traditional techniques to fabricate nanopatterns include electron beam lithography and focused ion beam. These techniques can create nanopatterns with precision but at the expense of cost and time. Therefore, electron beam lithography and focused ion beam techniques are most suitable for small areas of nanopatterns.

In conventional lithography one has to provide illumination of suitably short wavelength in order avoid optical diffraction from the conventional masks used. Conventional lithographic methods include double patterning lithography (DPL), self-aligned double patterning (SADP) lithography, and extreme ultra-violet (EUV) lithography. In the semiconductor industry, succeeding generations of semiconductor devices use finer line widths in order to fabricate more devices per unit area. In conventional lithography, line widths have decreased from 1 micron (1 μm) to 45 nanometers (45 nm). Improvements in lithographic systems that have been implemented include using shorter wavelength illumination, and using liquid immersion methods (for example using water with n=1.44 as compared to air with n=1.0). Estimates of line widths for which immersion technology is expected to be useful range from 32 nm, through 22 nm, down to 15 nm. Efforts to shorten the illumination wavelength to 13.5 nm (e.g., extreme UV) to reach line widths of 11 nm add complications including added expense, the loss of resolution as a result of secondary electron emission, and the necessity to operate in vacuum.

Nanoimprint lithography is one of the techniques that have been used to create large area of nanopatterns. This technique is versatile but is limited when fabricating certain patterns, such as isolated metal islands, on a delicate surface where pressure and physical compression need to be kept minimal. Laser interferometry is another way to create large area of nanopatterns. The technique requires mirrors and other optics with large scale to be able to produce large areas of nanopatterns, which can be cumbersome and expensive. Photolithography is a traditional way to make large areas of patterns of larger than wavelength scale. Due to the light scattering effect (or diffraction limit effect), photolithography has not been able to make patterns of sub-wavelength scale.

Electron beam (e-beam) lithography (or “direct-write” lithography) is a method that does not require a mask, and which can avoid the diffraction limit problem, but suffers from very slow writing speed (low throughput), and must be carried out in vacuum.

The International Technology Roadmap for Semiconductors (ITRS) is an international collaboration of chip manufacturers, equipment suppliers and researchers that provides projected goals and milestones which are projected to occur in this mature but dynamic industry. The ITRS document has been released as an annual edition since 1999. The ITRS document outlines a 15 year forward looking roadmap of technical challenges and prospective solutions to those challenges. In the 2009 document, lithography is covered in a 17 page section entitled “INTERNATIONAL TECHNOLOGY ROADMAP FOR SEMICONDUCTORS 2009 EDITION LITHOGRAPHY.” A copy of the document is appended hereto and is a part of this description.

A nanoarray is an arrangement of nanofeatures, generally on or in a substrate. As described by J. Ji, et.al. in “High-Throughput Nanohole Array Based System To Monitor Multiple Binding Events in Real Time”, Analytical Chemistry 80(7): 2491-2498, 2008, nanoarrays have been used to intensify light for projection of an image on a CCD chip. The resolution of the described system was limited by the CCD chip pixel size, typically in the micron range, which is a larger dimension that the wavelength of the illumination radiation. The image of an array of nano-apertures was applied as a sensitive detection platform to monitor the biological reactions occurring on the apertures. Another light intensifier and concentrator nano-aperture array was described by F. Huang, et al. in “Focusing of light by a nanohole array”, Applied Physics Letters 90(9): 091119/1-091119/3, 2007.

A number of problems in lithographic systems and methods have been observed. These problems include how one can attain feature sizes below 22 nm, how such systems can be operated effectively, and how such systems can be constructed and operated at reasonable cost.

There is a need for lithographic systems and methods for large area fabrication of nanopatterns at reasonable cost and throughput.

### SUMMARY OF THE INVENTION

According to one aspect, the invention features a nanomask for generating an illumination pattern. The nanomask includes a layer having a first surface and a second surface and a plurality of resonant nano-features disposed on at least a selected one of the first surface and the second surface. The nanomask is configured to provide an illumination pattern adjacent to the second surface. The illumination pattern has dimensions smaller than a wavelength λ of electromagnetic radiation used to illuminate the first surface of the layer in a single illumination.

In one embodiment, the layer includes a substrate having a plurality of patches distributed thereon, the substrate transparent to light at the wavelength λ.

In another embodiment, the plurality of patches comprise a patch shape selected from the group of patch shapes consisting of a sphere, a disk, a cone or frustum of a cone, polygon, and combinations thereof.

In yet another embodiment, the resonant nano-features comprise a plurality of sub-wavelength apertures having a dimension smaller than the wavelength λ disposed on a substrate.

In yet another embodiment, the apertures comprise a shape selected from the group of shapes consisting of a triangular, a rectangular, a polygonal shape, a circular shape and combinations thereof.

In yet another embodiment, the resonant nano-features comprise a shape selected from the group of shapes consisting of a groove, a ring, a depression, a dip, a bump, and combinations thereof.

In yet another embodiment, the nanomask includes a metal selected from the group of metals consisting of silver, gold, copper, titanium, aluminum, chromium, and combinations thereof.

In yet another embodiment, the nanomask includes an oxide selected from the group of oxides consisting of indium tin oxide, zinc oxide, and aluminum-doped zinc oxide.

In yet another embodiment, the layer has a thickness of less than 10 times a skin depth.

In yet another embodiment, the nanomask includes a plurality of layers.

In yet another embodiment, the nanomask is used in combination with a source of illumination that is configured to provide at least a wavelength λ to illuminate the first surface. A holder is configured to position relative to the mask an object to be illuminated with an illumination pattern having dimensions smaller than the wavelength λ. A control is configured to control during a single illumination at least one of: a time of exposure of the object, an intensity of exposure of the object and a position of the object relative to the nanomask.

According to one aspect, the invention features a nanopatterning method, which includes the steps of: providing a nanomask; providing an object having a surface to be nanopatterned, the surface of the object covered with a photoresist layer; exposing in a single illumination the photoresist layer with light having a wavelength λ longer than at least one dimension of a desired nanopattern; and developing the photoresist layer to provide a nanopattern on the surface of the object.

In one embodiment, the nanopatterning method further includes the step of performing a selected one of deposition and etching on the surface of the object through the developed photoresist layer.

In another embodiment, the step of performing a selected one of deposition and etching comprises a vapor deposition method selected from the group consisting of sputter deposition, chemical vapor deposition, thermal evaporation, electron beam evaporation, cathodic arc evaporation, and laser ablation.

In yet another embodiment, the step of performing a selected one of deposition and etching includes an etching method selected from the group of etching methods consisting of wet etching, dry etching and electrochemical polishing.

In yet another embodiment, the nanopatterning method further includes the step of removing the photoresist after the step of deposition or etching

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 illustrates the disclosed process, according to principles of the invention.

FIG. 2 shows a block diagram of an exemplary system suitable to perform the inventive method.

FIG. 3 shows an exemplary flow chart illustrating the inventive method.

FIG. 4 illustrates an exemplary embodiment of incident photons coupling with surface plasmons on a nanomask, according to principles of the invention.

FIG. 5 illustrates an exemplary embodiment of a nanomask having circular apertures and the conical regions of photoresist that are effectively exposed to photons, according to principles of the invention.

FIG. 6 illustrates an exemplary embodiment of a process by which a photoresist development step and a metal deposition step results in cylinder shapes of metals being formed on the surface of a substrate, according to principles of the invention.

FIG. 7A illustrates an exemplary embodiment of the result when light containing both resonant and non-resonant wavelengths is employed according to principles of the invention.

FIG. 7B illustrates an exemplary embodiment of the result when light containing resonant wavelengths is employed according to principles of the invention.

FIG. 8A shows a top view of an exemplary nanomask containing periodic subwavelength apertures in a surface plasmon-supporting metal film.

FIG. 8B shows a side view of the nanomask of FIG. 8A.

FIG. 9A shows an illustration of a top view of a plurality of apertures which do not completely penetrate a layer.

FIG. 9B shows an illustration of a side view of the layer of FIG. 9A.

FIG. 10 shows an illustration of a top view of a plurality of circular patches disposed on a layer.

FIG. 11 shows an illustration of a top view of a plurality of hexagonal shaped patches disposed on a layer.

FIG. 12 illustrates exemplary embodiments of non-periodic apertures that can also be introduced into nanomasks, according to principles of the invention.

FIG. 13A illustrates an exemplary embodiment of additional layers of materials can be added to enhance adhesion of the nanomask onto the substrate, according to principles of the invention.

FIG. 13B illustrates an exemplary embodiment in which an optically opaque layer is inserted between plasmonic layers to enhance the optical opaqueness of the nanomask, according to principles of the invention.

### DETAILED DESCRIPTION

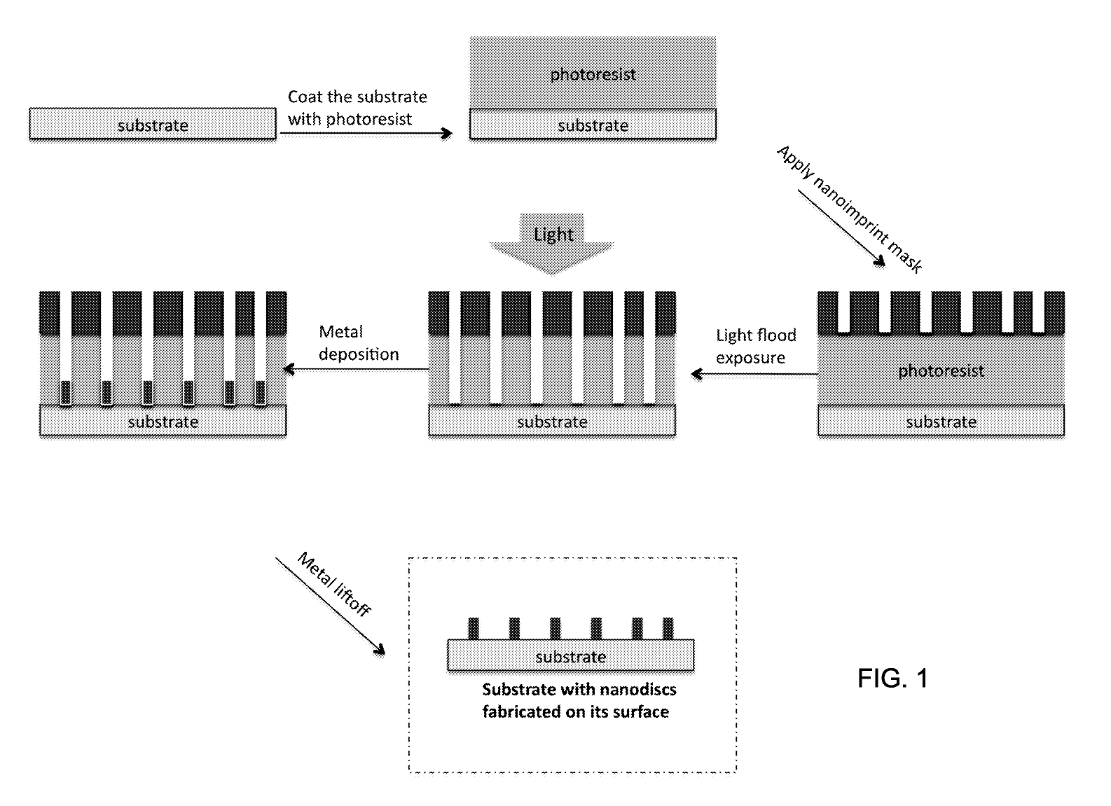

This invention discloses a method by which sub-wavelength patterns can be created using a plasmonic nanomask and light flood exposure. FIG. 1 illustrates the disclosed process. In this process, the surface upon which a nanopattern is to be fabricated is first coated with a photoresist. The coating method can be spin coating, roller rod spread coating, spraying coating or inkjet printing. A plasmonic nanomask is then applied to the photoresist surface. Light incident onto the photomask exposes the defined regions of photoresist. Following development of the photoresist, there is a deposition step to deposit a material or an etching step to remove a material from areas exposed in the developed photoresist pattern resulting in a desired nanopattern. Typically, the nanomask can be re-used, such as in a step-and-repeat photoresist exposure process. In some nanomask single-use embodiments, following photoresist develop and metal deposition, the nanomask can be peeled off using a standard metal liftoff process, or a single-use nanomask can remain on the assembly.

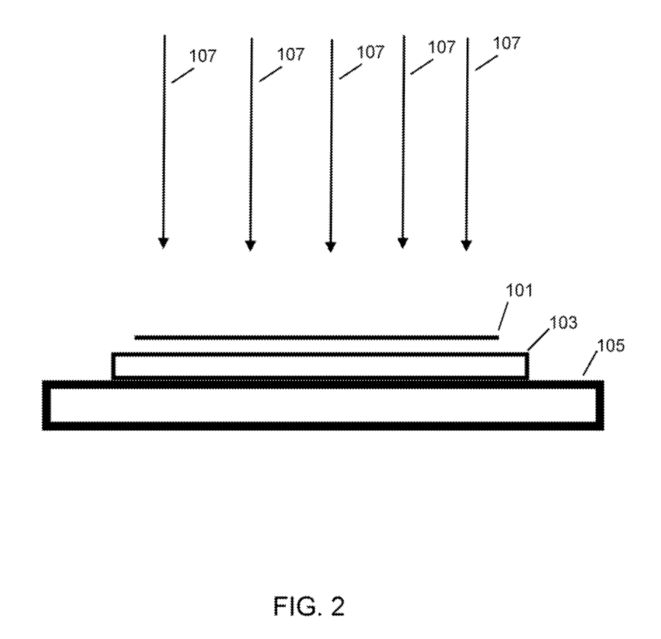

A system to perform the inventive process of by which sub-wavelength patterns can be created using a nanomask with nanofeatures followed by light flood exposure of a light including a wavelength λ is now described. FIG. 2 shows an exemplary block diagram of such a system. A nanomask 101 (nanofeatures not shown) is used in combination with a source of illumination 107 that is configured to provide at least a wavelength λ to illuminate a first surface of the nanomask 101. A holder 105 is configured to position relative to the nanomask, an object 103 to be illuminated with an illumination pattern having dimensions smaller than the wavelength λ (i.e. sub-wavelength dimensions). A control (not shown) is configured to control, during a single illumination, the time of exposure of the object 103 and/or the intensity of exposure of the object 103 and a position of the object relative to the nanomask 101.

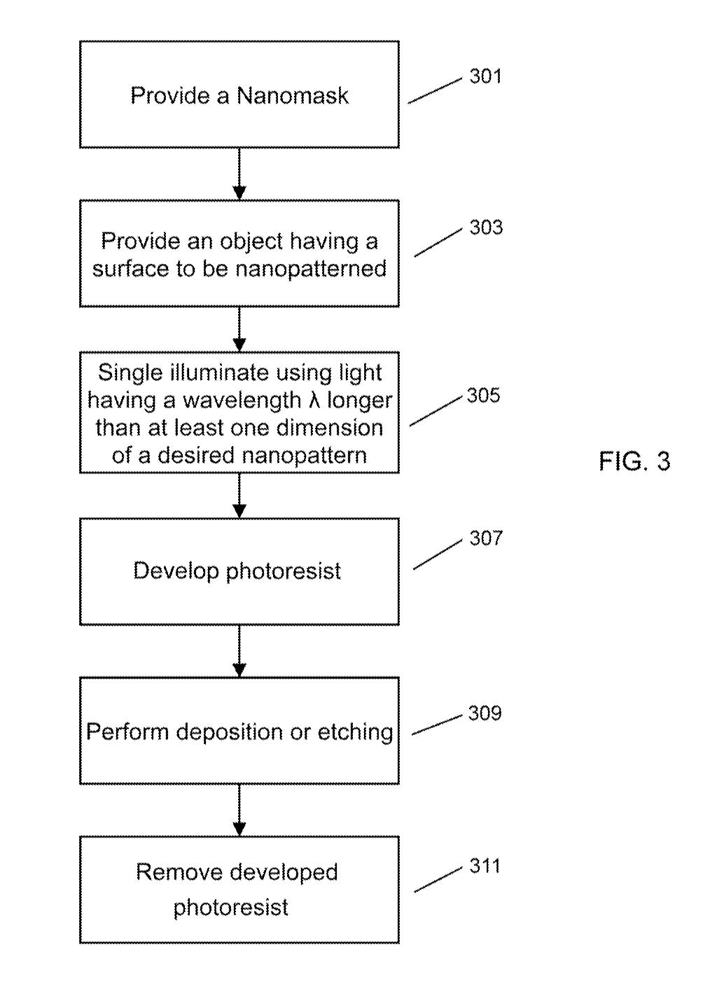

FIG. 3 shows a flow chart for one embodiment of the inventive nanopatterning method. At step 301, a nanomask is provided. At step 303, an object having a surface to be nanopatterned is provided (the surface of the object covered with a photoresist layer). At step 305, a single illumination exposes the photoresist layer with light having a wavelength λ longer than at least one dimension of a desired nanopattern, and at step 307, the photoresist layer is developed to provide a nanopattern on a surface of the object. Optionally, following step 307, there is a step 309 of either deposition or etching on the surface of the object through the developed photoresist layer. A deposition or etching step can use any suitable deposition or etching technique such as, for example, sputter deposition, chemical vapor deposition, thermal evaporation, electron beam evaporation, sputtering evaporation, cathodic arc evaporation, laser ablation, or chemical vapor evaporation. An etching step can include wet etching, dry etching and electrochemical polishing. Next, in an optional step 311, the developed photoresist can be removed following the step of deposition or etching.

### Exemplary Methods Suitable for Nanomask Manufacture

The nanomask can be made by nanoimprint lithography, laser interferometry, e-beam lithography, use of focused ion beams, or other techniques. In some embodiments, the nanomask can be made as a stand-alone film, or on a flexible substrate such as PEN, or a rigid substrate such as glass, or quartz. Dennis Slafer of MicroContinuum, Inc. of Cambridge, Mass., has described several manufacturing techniques and methods that are believed to be suitable for the manufacture plasmonic nanomasks as described herein. For example, U.S. patent application Ser. No. 12/358,964, ROLL-TO-ROLL PATTERNING OF TRANSPARENT AND METALLIC LAYERS, filed Jan. 23, 2009, published as US 2009/0136657 A1 describes and teaches one exemplary manufacturing process to create metallic films having a plurality of nanofeatures suitable for use to make plasmonic nanomasks as described herein. Also, U.S. patent application Ser. No. 12/270,650, METHODS AND SYSTEMS FOR FORMING FLEXIBLE MULTILAYER STRUCTURES, filed Nov. 13, 2008, published May 28, 2009 as US 2009-0136657 A1, U.S. patent application Ser. No. 11/814,175, REPLICATION TOOLS AND RELATED FABRICATION METHOD AND APPARATUS, filed Aug. 4, 2008, published Dec. 18, 2008 as US 2008-0311235 A1, U.S. patent application Ser. No. 12/359,559, VACUUM COATING TECHNIQUES, filed Jan. 26, 2009, published Aug. 6, 2009 as US 2009-0194505 A1, and PCT Application No. PCT/US2006/023804, SYSTEMS AND METHODS FOR ROLL-TO-ROLL PATTERNING, filed Jun. 20, 2006, published Jan. 4 2007 as WO 2007/001977, describe and teach related manufacturing methods which are also believed to be useful for manufacturing nanomasks as described herein. Each of the above identified United States and PCT applications is hereby incorporated herein by reference in its entirety for all purposes.

Laser interferometry is another manufacturing process that is believed to be suitable for the manufacture of plasmonic nanomasks as described herein. For example, in U.S. Pat. No. 7,304,775, Actively stabilized, single input beam, interference lithography system and method, D. Hobbs and J. Cowan described an interference lithography system that is capable of exposing high resolution patterns in photosensitive media and employing yield increasing active stabilization techniques. U.S. Pat. No. 7,304,775 is hereby incorporated herein by reference in its entirety for all purposes

### The Function of the Plasmonic Nanomask

The plasmonic nanomask can be made of materials that can sustain surface plasmons. Examples of such materials are, but not limited to, gold, silver, copper, and aluminum. The function of the plasmonic nanomask is to allow surface plasmon resonance generation that helps light to overcome scattering loss and pass through subwavelength apertures.

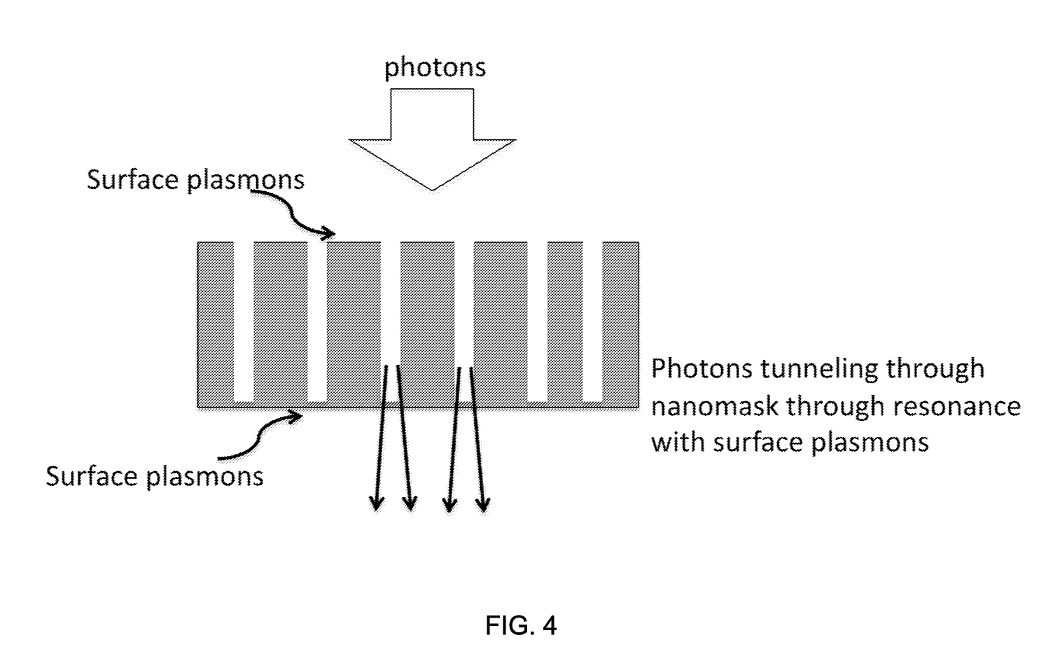

As shown in FIG. 4, incident photons couple with surface plasmons on the nanomask to create surface plasmon resonance that helps photons to tunnel through the sub-wavelength apertures, and be re-emitted from the other side of the nanomask. Surface plasmons on the other side of the nanomask help the process of re-emission and formation of propagating photons. The re-emitted light has low divergence that ensures the sub-wavelength size and fine resolution of the light beams emitted from individual apertures.

### Effect of the Low Divergence of Re-Emitted Light Beams

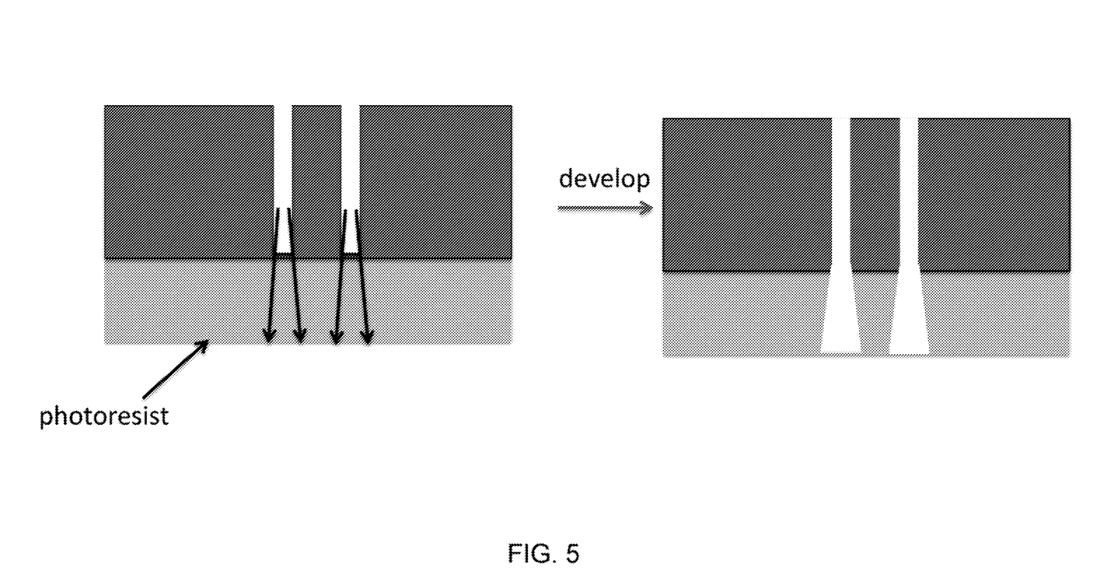

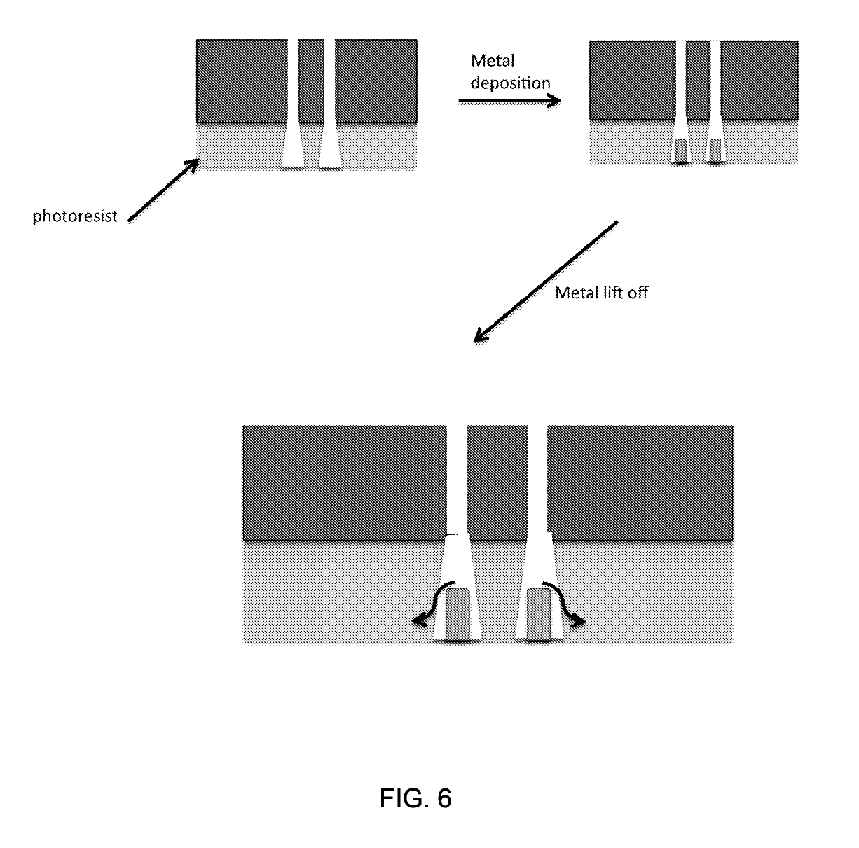

The low divergence of the light beams creates undercuts that ensure the success of the following photolithography steps. As shown in FIG. 5, for a nanomask having circular apertures, conical regions of photoresist are effectively exposed to photons by the disclosed assembly of a nanomask and photoresist. After the photoresist development step and the metal deposition step(s), cylinder shapes of metals are formed on the surface of substrate as shown in FIG. 6. The space between the conical shape of the developed regions of photoresist and the cylindrical shapes of the metal gives lift off reagent molecules easy access to the photoresist layer, ensuring a successful lift off

### Choice of Illumination Source

According to standard diffraction theory, apertures much smaller than the wavelength of light transmit poorly and diffract light in all directions, resulting in low intensity and high divergence of the transmitted light. This causes the limitation of standard photolithography methods that can only effectively created patterns having features sizes larger than the wavelength of the incoming light. One solution that has been applied to avoid the errors cause by the diffraction effect involves double lithography (e.g., summing the effect of two separate lithographic illuminations) with associated extra steps and costs in both expenses and time). Using the disclosed methods of this application, patterns with feature sizes much smaller than the wavelength of the incident light can be created with a single illumination.

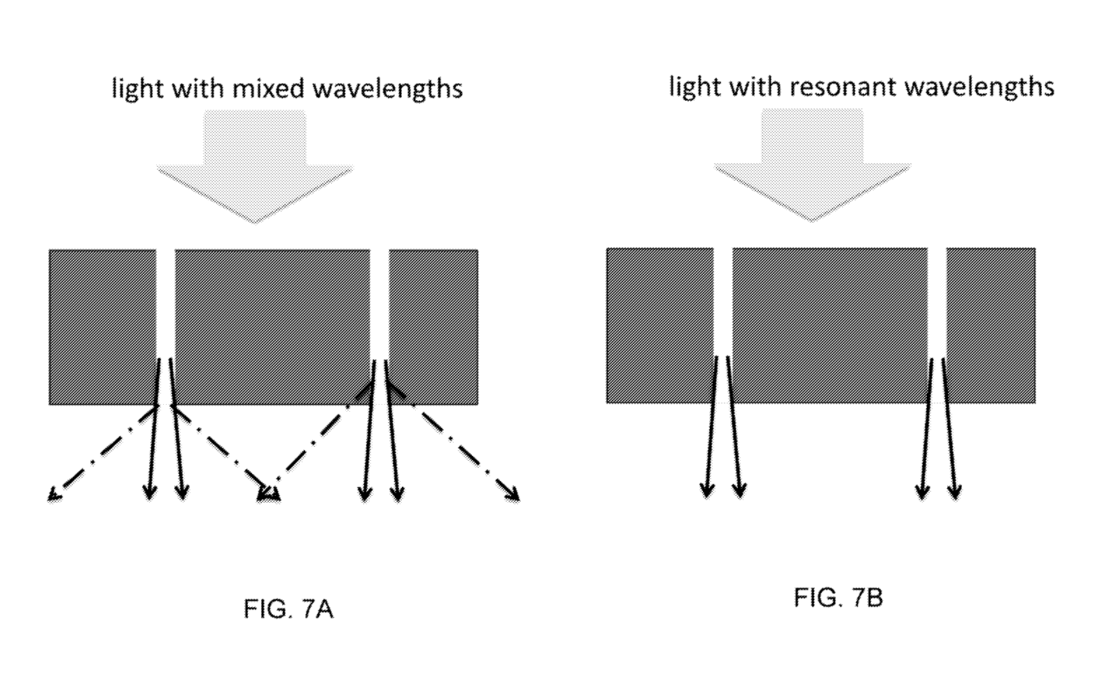

A preferred embodiment to create highly resolved light beams involves using light that contains wavelengths that can resonant with a plasmonic nanomask, with other wavelengths present in minimal intensity so much as possible. As shown in FIG. 7A, when light containing both resonant and non-resonant wavelengths is employed, two types of light beams are created. One type of beam is created by coupling of the photons with surface plasmons, tunneling of the plasmons, and re-emission of the photons. This type of light beam has low-divergence, and is highly resolved from the light beam created by a neighboring aperture. Another type of light beams is created by classic diffraction, which is highly un-resolved and has low intensity. The result of this mixed light source is light beams with mixed resolution. When only resonant light is used, as shown in FIG. 7B, only the highly resolved light beam is obtained, which leads to a higher quality of the resulted nanopatterns.

### Nanomask

We now describe various embodiments of the nanomask in more detail. A nanomask for generating a nano-illumination pattern has a layer having a first surface and a second surface and a plurality of resonant nano-features disposed on the first surface and/or the second surface. A wavelength λ of electromagnetic radiation is used to illuminate the first surface of the layer in a single illumination. The nanomask is configured to provide an illumination pattern adjacent to the second surface. The illumination pattern has dimensions smaller than a wavelength λ of electromagnetic radiation which was used to illuminate the first surface of the layer.

In one embodiment, the nanomask includes patches. Typically, in a patches embodiment, the patches are opaque or translucent at wavelength λ and the layer includes a support or substrate which is transparent at wavelength λ. A plurality of patches is distributed on the transparent substrate. The plurality of patches can include patch shapes such as, for example, spheres, disks (e.g. cylindrical protrusions), and cones or frustums of a cone (e.g. tapered cylindrical protrusions). Patches can be disposed adjacent to each other (i.e. touching each other). In most embodiments, the spacing between the patches is configured to create a nanopattern, including the resonant nano-features of the inventive plasmonic nanomask. The dimensions of the patches themselves (as opposed to the inter-patch dimensions) are not necessarily subwavelength dimensions.

In another embodiment, the resonant nano-features of the nanomask can include apertures. Such apertures are defined in a substrate material of the nanomask layer. Generally, the apertures are sub-wavelength apertures having a dimension smaller than the wavelength λ. Aperture shapes can be triangular, rectangular, polygonal, circular and any combinations thereof. Other suitable aperture shapes also include grooves, rings, depressions, dips, bumps, and combinations thereof.

Turning now to suitable materials, a nano mask can include a metal such as silver, gold, copper, titanium, aluminum, chromium, and combinations thereof. A nanomask can also include an oxide, such as for example, indium tin oxide, zinc oxide, and aluminum-doped zinc oxide.

### EXAMPLES

1) A nanomask includes a metal layer of any suitable metal, such as those described hereinabove, and has disposed within a layer of the nanomask, nanofeature apertures. Such apertures can be openings in air, contain a gas or any other suitable material, typically a dielectric.

2) A nanomask includes patches made of any suitable metal disposed on a substrate which is transparent to light at a wavelength λ. The substrate is typically made of a dielectric material.

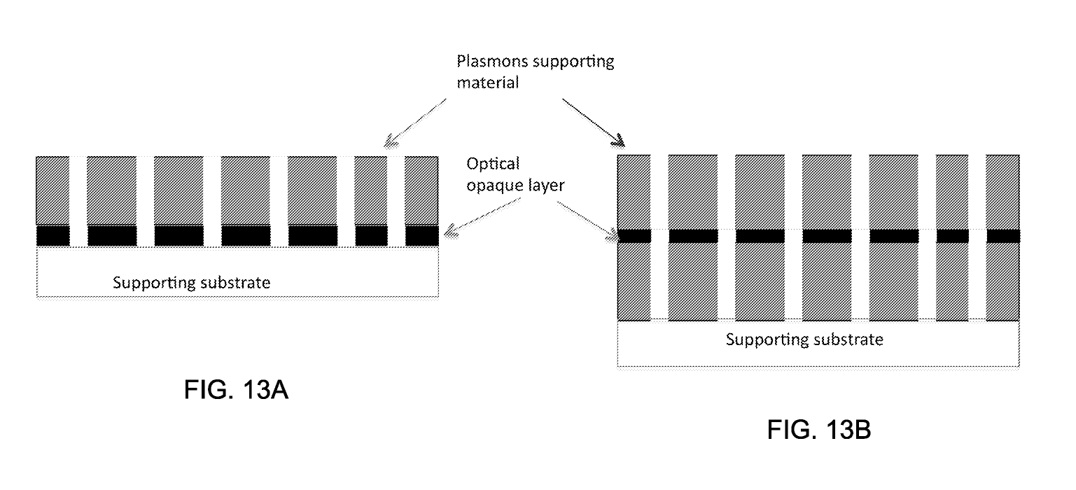

3) A nanomask can include an extremely thin metal layer, typically less than 2 times skin depth of the incident light, of any suitable metal, such as those described hereinabove, and a thin opaque layer of any suitable metal such as chromium or titanium. The function of the opaque layer is to prevent unwanted light leaking through the extremely thin metal layer in the undesired regions, while the extremely thin metal layer promotes collection and concentration of incident photons through the defined regions (e.g. as illustrated by FIG. 13a).

4) A nanomask includes multiple extremely thin metal layers, typically less than 2 times skin depth of the incident light, of any suitable metal, such as those described hereinabove, and a thin opaque layer of any suitable metal such as chromium or titanium in between the extremely thin multiple metal layers. The function of the opaque layer is to prevent unwanted light leaking through the extremely thin metal layer in the undesired region, while the multiple extremely thin metal layer promotes collection, concentration, and tunneling of incident photons through the defined regions (e.g. as illustrated in FIG. 13B).

### Plasmonic Layers

In several co-pending applications we described structures, materials and fabrication techniques for nanoarrays used as plasmonic layers. In general, such plasmonic layers can be manufactured as standalone devices for use as a plasmonic nanomask according to the present invention. For example in U.S. patent application Ser. No. 12/777,559, INTEGRATED SOLAR CELL NANOARRAY LAYERS AND LIGHT CONCENTRATING DEVICE, filed May 11, 2010, published Nov. 18, 2010 as US 2010/0288352 A1, we described light management device layers that employ nanoarrays having nanofeatures. In U.S. patent application Ser. No. 12/758,373, PLANAR PLASMONIC DEVICE FOR LIGHT REFLECTION, DIFFUSION AND GUIDING, filed Apr. 12, 2010 published Oct. 14, 2010 as US 2010/0259826 A1, we described plasmonic layers including a planar plasmonic device employing a textured surface or a compound nanofeature. In U.S. patent application Ser. No. 12/921,388, INTEGRATED SOLAR CELL WITH WAVELENGTH CONVERSION LAYERS AND LIGHT GUIDING AND CONCENTRATING LAYERS, filed Sep. 7, 2010, published Jan. 20, 2011 as US 2011/0011455 A1, and U.S. patent application Ser. No. 12/921,392, INTEGRATED PLANAR DEVICE FOR LIGHT GUIDING, CONCENTRATING, AND WAVELENGTH SHIFTING, filed Sep. 7, 2010, published Jan. 20, 2011 as US 2011/0013253 A1, we described layers with nanofeatures in the context of solar cells. In U.S. patent application Ser. No. 12/621,252, SURFACE PLASMON WAVELENGTH CONVERTER, filed Nov. 19, 2009, published May 27, 2010 as US 2010/0126566 A1, we described layers with nanofeatures in the context of solar cells. Each of the applications described hereinabove is incorporated herein by reference in its entirety for all purposes.

### Nanomask Design

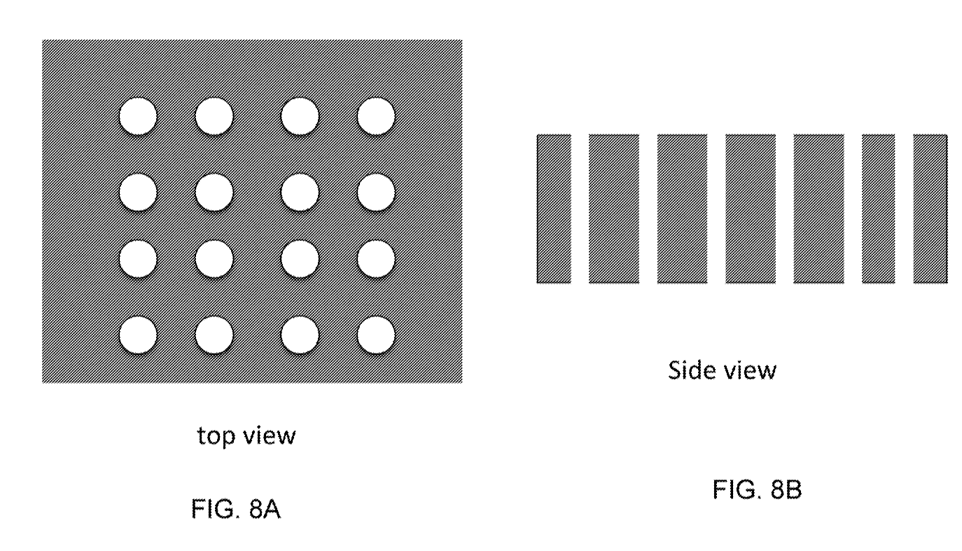

An exemplary nanomask design is shown in FIG. 8A and FIG. 8B. FIG. 8A shows a top view of a nanomask containing periodic subwavelength apertures in a surface plasmon-supporting metal film. FIG. 8B shows a side view of the nanomask of FIG. 8A. The thickness of the metal film preferably should be larger than the skin depth. In some preferred embodiments, the thickness of the metal film is between 2 to 10 times of the skin depth, for example ranging about 10 nm to 500 nm. In a preferred embodiment, the thickness of the metal film is less than 2 times of the skin depth. Thus, a nanomask layer generally has a thickness of less than 10 times a skin depth. The periodicity of the apertures on the nanomask creates resonant conditions for light of certain wavelengths to resonate with the surface plasmon. This nanomask is expected to create periodic nanopatterns on a desired surface.

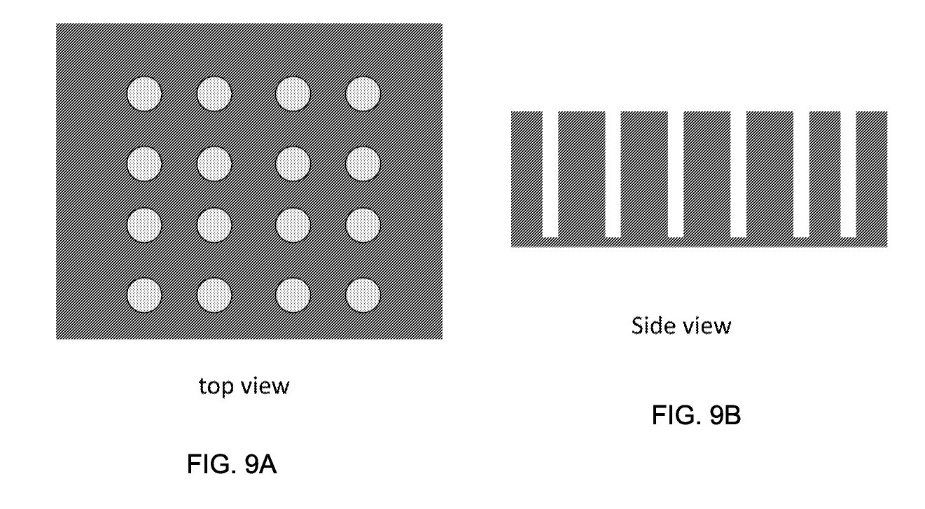

Turning now to exemplary embodiments having apertures, in some embodiments, the apertures can completely penetrate the layer of a nanomask. FIG. 8A, described hereinabove, for example, shows an illustration of a top view of a plurality of nanofeature apertures which go completely through a layer. In other embodiments, nanofeature apertures do not completely penetrate a layer of the nanomask. For example, FIG. 9A shows an illustration of a top view where the apertures do not completely penetrate a layer. FIG. 9B shows a side view of the layer of FIG. 9A.

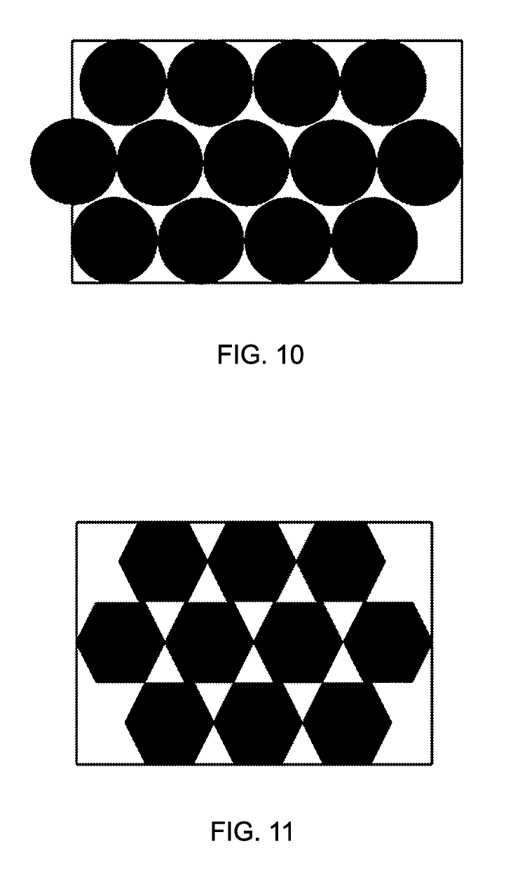

Turning now to exemplary embodiments using patches, FIG. 10 shows an illustration of a top view of a plurality of circular nano-patches disposed on a layer. FIG. 11 shows an illustration of a top view of a plurality of hexagonal shaped nano-patches disposed on a layer.

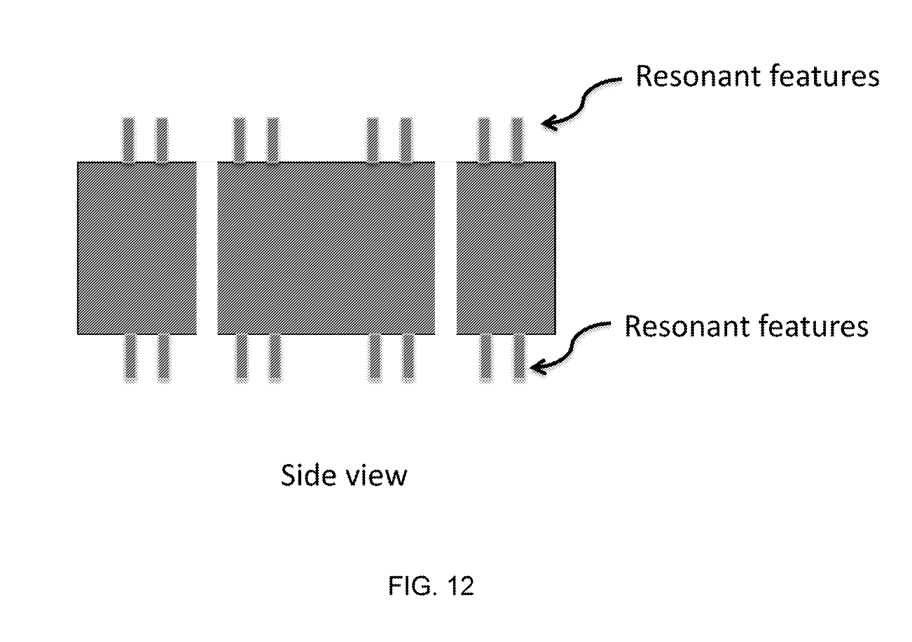

As shown in FIG. 12, a nanomask can contain non-periodic apertures, which through the disclosed method can create non-periodic nanopatterns on a desired surface. In this design, resonant features are introduced near sub-wavelength apertures to induce resonance between surface plasmon and photons, helping photons to tunnel through apertures without out loss from scattering and assisting resolution of the re-emitted photons. Although FIG. 12 shows resonant features present on both top and bottom sides of the nanomask, it is not necessary to have the resonant features on both sides. In some embodiments, nanomasks can be fabricated with resonant features on either the top side or the bottom side, and are expected to function in the disclosed method. Similar resonant features can also be introduced into nanomasks such as the nanomask depicted in FIG. 9A and FIG. 10, FIG. 11, to influence surface plasmon resonance and the quality of the light beams passed through the nanomask.

Although the apertures shown in FIG. 8A are round, the apertures can be of any other shape such as a triangule, a rectangule, a polygon, and combinations thereof. Resonant features can include grooves, rings, depressions, dips, bumps, and combinations thereof.

A nanomask can include a plurality of layers. As shown in FIG. 13A, additional layers of materials can be added to enhance adhesion of the nanomask onto the substrate. Such layers can be made of titanium, chromium or other materials. Such adhesion layer is expected to function well if it is relatively thinner than the plasmonic nanomask, ranging from 1 nm to 10 nm. Also, such a layer is preferred to be optically opaque. FIG. 13B shows an example of another embodiment of a stack of nanomask layers. In other embodiments, an optically opaque layer can be inserted between plasmonic layers to enhance the optical opaqueness of the nanomask, while ensuring the plasmonic effect of the nanomask.

Surface where Nanopatterns are to be Fabricated

One of the advantages of using the disclosed method to fabricate nanopatterns is that the method requires minimum interaction between the process and the surface where nanopatterns are to be fabricated. Throughout the process, photoresist functions as a protection layer that shields the surface from various process steps.

One example of a surface to be fabricated is a photovoltaic (PV) absorber layer where the surface properties are highly sensitive to pressure and mechanical forces such as surface scratching. Examples of the photovoltaic layer are, but not limited to, amorphous silicon, crystalline and poly-crystalline silicon, nano-crystalline and micro-crystalline silicon, copper indium gallium (di)selenide (CIGS), and cadmium telluride (CdTe).

### Applications

The disclosed method can be used to fabricate nanopatterns on various surfaces including photovoltaic absorber layers of solar cells. The nanopatterns can be fabricated on the front or back of a solar cell, or in between PV layers of a tandem solar cell.

In other embodiments, the nanomasks of the invention can be used in processing semiconductor materials such as silicon wafers. For such applications, the nanopatterns can be fabricated on any suitable semiconductor material.

### Definitions

NANOFEATURE: A nanofeature is any feature that can be described by a closed curve having a dimensional radius or length on the order of a nanometer. A nanofeature can be a “positive” nanofeature typically being defined by the presence of a material disposed within the closed curve. For example, a disk, typically present as a protrusion, can be made of a metal deposited on surface and having a circular diameter dimension on the order of a nanometer. We define such a disk as a nanofeature. A nanofeature can also be a “negative” nanofeature being defined by the absence of a material disposed within the closed curve, typically as a depression or as an aperture. For example, a square depression etched into a surface and having a length of one side of the square shape on the order of a nanometer is also defined as a nanofeature. A negative nanofeature is also defined as including a space between features, which may or may not be nanofeatures themselves. For example, the space between two or more patches (patches of any suitable shape) having a length on the order of a nanometer is also defined as a nanofeature.

Nanofeatures are further defined as including (i) one or more types made of metallic nanoscale structures or particles typically embedded in a dielectric (including a solid dielectric, liquid dielectric, air, dielectric gas, or vacuum), insulator, semiconductor, polymer, or other material having a different dielectric coefficient than the metallic nanoscale structures or particles such as an oxide film, and (ii) one or more type of non-metallic nanoscale particles or structures made of a dielectric material (including a solid dielectric, liquid dielectric, air, dielectric gas, or vacuum), semiconductor, insulator, polymer or other material typically embedded in a metallic material having a different dielectric coefficient than the non-metallic nanoscale particles materials. A “nanofeature layer”, such as the one or more layers found in a nanomask, is defined as including (i) layers having nanofeatures disposed therein or thereon, and (ii) layers of metals or other conductive media that have an array of nanoscale voids, depressions, protrusions, or other nanoscale patterns.

APERTURE: Aperture is defined herein to include shapes that make a complete penetration through a layer (e.g. FIG. 8B) as well as shapes which make an incomplete penetration through the layer of a nanomask (e.g. FIG. 9B).

SUB-WAVELENGTH: The term “sub-wavelength” is defined to mean “shorter than a wavelength,” especially shorter than a wavelength of electromagnetic radiation applied as an illumination to a first surface of a mask.

### Theoretical Discussion

Although the theoretical description given herein is thought to be correct, the operation of the devices described and claimed herein does not depend upon the accuracy or validity of the theoretical description. That is, later theoretical developments that can explain the observed results on a basis different from the theory presented herein will not detract from the inventions described herein.

Any patent, patent application, or publication identified in the specification is hereby incorporated by reference herein in its entirety. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

While the present invention has been particularly shown and described with reference to the preferred mode as illustrated in the drawing, it will be understood by one skilled in the art that various changes in detail can be affected therein without departing from the spirit and scope of the invention as defined by the claims.

What is claimed is:

1. A nanomask for generating an illumination pattern, comprising:
a layer having a first surface and a second surface and a plurality of resonant nano-features disposed on at least a selected one of said first surface and said second surface, said nanomask configured to provide an illumination pattern adjacent to said second surface, said illumination pattern having dimensions smaller than a wavelength λ of electromagnetic radiation used to illuminate said first surface of said layer in a single illumination.

2. The nanomask of claim 1, wherein said layer comprises a substrate having a plurality of patches distributed thereon, said substrate transparent to light at said wavelength λ.

3. The nanomask of claim 2, wherein said plurality of patches comprise a patch shape selected from the group of patch shapes consisting of a sphere, a disk, a cone, a frustum of a cone, a polygon, and combinations thereof.

4. The nanomask of claim 1, wherein said resonant nano-features comprise a plurality of sub-wavelength apertures having a dimension smaller than said wavelength λ disposed on a substrate.

5. The nanomask of claim 4, wherein said apertures comprise a shape selected from the group of shapes consisting of a triangule, a rectangule, a polygon, a circle and combinations thereof.

6. The nanomask of claim 4, wherein said resonant nano-features comprise a shape selected from the group of shapes consisting of a groove, a ring, a depression, a dip, a bump, and combinations thereof.

7. The nanomask of claim 1, wherein said nanomask comprises a metal selected from the group of metals consisting of silver, gold, copper, titanium, aluminum, chromium, and combinations thereof.

8. The nanomask of claim 1, wherein said nanomask comprises an oxide selected from the group of oxides consisting of indium tin oxide, zinc oxide, and aluminum-doped zinc oxide.

9. The nanomask of claim 1, wherein said layer has a thickness of less than 10 times a skin depth.

10. The nanomask of claim 1, wherein said nanomask comprises a plurality of layers.

11. A nanomask according to claim 1, in combination with:
a source of illumination that is configured to provide at least a wavelength λ to illuminate said first surface;
a holder configured to position relative to said mask an object to be illuminated with an illumination pattern having dimensions smaller than said wavelength λ; and
a control configured to control during a single illumination at least one of a time of exposure of said object, an intensity of exposure of said object and a position of said object relative to said nanomask.

12. A nanopatterning method, comprising the steps of:
providing a nanomask according to claim 1;
providing an object having a surface to be nanopatterned, said surface of said object covered with a photoresist layer;
exposing in a single illumination said photoresist layer with light having a wavelength λ longer than at least one dimension of a desired nanopattern; and
developing said photoresist layer to provide a nanopattern on said surface of said object.

13. The nanopatterning method of claim 12, further comprising the step of performing a selected one of deposition and etching on said surface of said object through said developed photoresist layer.

14. The nanopatterning method of claim 13, wherein said step of performing a selected one of deposition and etching comprises a vapor deposition method selected from the group consisting of sputter deposition, chemical vapor deposition, thermal evaporation, electron beam evaporation, cathodic arc evaporation, and laser ablation.

15. The nanopatterning method of claim 13, wherein said step of performing a selected one of deposition and etching comprises an etching method selected from the group of etching methods consisting of wet etching, dry etching and electrochemical polishing.

16. The nanopatterning method of claim 14, further comprising the step of removing said photoresist after the step of deposition or etching.
